(19) United States
(12) Patent Application Publication
(10) Pub. No.: US 2006/0233210 A1
(43) Pub. Date: Oct. 19, 2006

(54) Semiconductor laser device, method for manufacturing the same, and optical pickup device using the same

(76) Inventor: Toru Takayama, Nara (JP)

Correspondence Address: MCDERMOTT WILL & EMERY LLP, 600 13TH STREET, N.W., WASHINGTON, DC, 20005-3096, US

(21) Appl. No.: 11/319,612

(22) Filed: Dec. 29, 2005

(30) Foreign Application Priority Data
Apr. 13, 2005 (JP) 2005-115807

(51) Int. Cl. H01S 5/00

(52) U.S. Cl. 372/43.01

(57) ABSTRACT

The present invention provides a semiconductor laser device having a high reliability and desirable temperature characteristics while being a high-power device. An active layer, and two cladding layers sandwiching the active layer therebetween are formed on a substrate. One of the cladding layers forms a mesa-shaped ridge, and the ridge includes a waveguide region diverging into at least two branches. With this configuration, the density of carriers injected into the rear facet portion of the active layer is decreased, whereby it is possible to improve the temperature characteristics of the semiconductor laser. While the device includes a region across which the ridge bottom width varies continuously, the ridge bottom width is constant near the facet.

### BACKGROUND OF THE INVENTION

1. Field of the Invention

The present invention relates to a semiconductor laser device and a method for manufacturing the same and, more particularly, to a semiconductor laser device suitable for use in an optical pickup device and a method for manufacturing the same. The present invention relates also to an optical pickup device using such a semiconductor laser device.

2. Description of the Background Art

Semiconductor laser devices are widely used in various fields of application. Particularly, AlGaInP semiconductor laser devices, which are capable of outputting laser light having a wavelength in a 650 nm band, are widely used as light sources of optical disk systems. In recent years, GaN semiconductor laser devices have been proposed in the art, which are capable of outputting laser light having a wavelength in a 405 nm band, and further performance improvements are expected in optical disk systems.

A known type of such a semiconductor laser device has a double hetero structure including an active layer and two cladding layers sandwiching the active layer therebetween, wherein one of the cladding layers forms a mesa-shaped ridge (see, for example, Japanese Laid-Open Patent Publication No. 2001-196694).

FIG. 11 is a front view showing a structure of a conventional semiconductor laser device. FIG. 11 shows an example of an AlGaInP semiconductor laser device. The composition ratio of each layer will be omitted in the following description. The semiconductor laser device shown in FIG. 11 includes an n-type GaAs buffer layer 102, an n-type GaInP buffer layer 103 and an n-type (AlGa)InP cladding layer 104, which are layered in this order on an n-type GaAs substrate 101 whose principal plane is inclined from the (100) plane by 15° in the [011 ] direction.

A strained quantum well active layer 105, a p-type (AlGa)InP first cladding layer 106, a p-type (or undoped) GaInP etching stop layer 107, a p-type (AlGa)InP second cladding layer 108, a p-type GaInP intermediate layer 109 and a p-type GaAs cap layer 110 are layered on the n-type (AlGa)InP cladding layer 104.

The p-type (AlGa)InP second cladding layer 108, the p-type GaInP intermediate layer 109 and the p-type GaAs cap layer 110 are formed on the p-type GaInP etching stop layer 107 as a ridge having a forward mesa shape. An n-type GaAs current blocking layer 111 is formed on the p-type GaInP etching stop layer 107 and on the side surface of the ridge, and a p-type GaAs contact layer 112 is layered on the n-type GaAs current blocking layer 111 and the p-type GaAs cap layer 110 located in an upper portion of the ridge. Note that the strained quantum well active layer 105 is formed by an (AlGa)InP layer and a GaInP layer.

In the semiconductor laser device shown in FIG. 11, the flow of a current injected through the p-type GaAs contact layer 112 is constricted within the ridge portion by the n-type GaAs current blocking layer 111, and is thus concentrated at a portion of the strained quantum well active layer 105 near the bottom of the ridge. Thus, it is possible to realize an inverted carrier population that is required for laser oscillation despite a small injected current of some tens of mA. Then, light is generated through recombination of carriers.

At this point, with respect to the direction perpendicular to the strained quantum well active layer 105, light is confined by the opposing cladding layers, i.e., the n-type (AlGa)InP cladding layer 104 and the p-type (AlGa)InP first cladding layer 106. Moreover, with respect to the direction parallel to the strained quantum well active layer 105, the GaAs current blocking layer 111 absorbs generated light, thereby confining light. Then, laser oscillation occurs when the gain produced by the injected current exceeds the loss through the waveguide in the strained quantum well active layer 105.

In general, the bandgap energy of a semiconductor laser device varies depending on the temperature, and therefore the wavelength and the threshold value have some temperature dependence. For example, it is known in the art that the threshold current Ith(T) at temperature T typically has a temperature dependence expressed by the following expression (e.g., “Semiconductor Laser”, 1st edition, Ed. Kenichi Iga, Ohmsha Ltd., October 1994, p. 6).
Ith=Ith(T′)exp[(T−T′)/T0]
where T0, called “characteristic temperature”, is a factor indicating the degree of sensitivity of the threshold current to a temperature variation. As is clear from the above expression, a semiconductor laser device with a larger value of the characteristic temperature T0 has a smaller temperature dependence, and can be said to be a device that is stable against temperature variations and is of high practical use. Accordingly, there is a demand for a device structure for semiconductor laser devices that realizes a greater value of the characteristic temperature T0.

### SUMMARY OF THE INVENTION

In recent years, the amount of information to be handled is increasing rapidly in various fields. Accordingly, there is a demand for an optical disk system capable of recording information and reproducing recorded information at a higher speed. A semiconductor laser device used in such an optical disk system needs to have a high output power.

Typically, in a high-power semiconductor laser device, the facet coating film on the front facet, through which laser light is outputted, has a reflectivity as low as about 5% while that on the rear facet has a reflectivity as high as 90% or more, so as to increase the external differential quantum efficiency ηd in the current-optical output power characteristics, whereby it is possible to obtain a high optical output power with a lower operating current. However, a semiconductor laser device with such a structure has a larger operating carrier density in a portion of the active layer near the rear facet than near the front facet. Therefore, when such a semiconductor laser device is operated to output light, it is likely to have a leak current, in which injected carriers leak from the rear facet portion of the active layer into a cladding layer. If the leak current increases, the radiation efficiency of the semiconductor laser device decreases, increasing the operating current value, which may deteriorate the temperature characteristics and decrease the reliability.

Moreover, with a high-power semiconductor laser device, the current injection area cannot be increased sufficiently to accommodate an increase in the operating current, thereby resulting in a high differential resistance (hereinafter “Rs”) in the current-voltage characteristics of the device. If the differential resistance Rs increases, the amount of heat generated in the semiconductor laser device also increases, thereby further deteriorating the temperature characteristics of the device. One way to increase the current injection area is to increase the size of the device itself. However, if the size of the device itself is increased, the manufacture becomes more difficult, thus lowering the yield and leading to an increase in cost.

Moreover, when a high-power semiconductor laser device is used in an optical disk system, the feedback light reflected off the optical disk is sometimes incident upon the semiconductor laser device. If the feedback light component becomes excessive, the semiconductor laser device may have mode-hopping noise, thereby deteriorating the S/N ratio of the reading signal. Typically, in order to suppress this phenomenon, a high-frequency current is superimposed on the driving current in a semiconductor laser device used in an optical disk system so as to output multimode laser light, thereby preventing the deterioration in the S/N ratio of the reading signal. However, as described above, if the differential resistance Rs of a semiconductor laser device increases, the change in the operating current in response to a change in the operating voltage tends to decrease. A decrease of the change in the operating current detracts from the multimode property of the oscillation spectrum and increases the coherent noise from the optical disk, thus lowering the reliability of the semiconductor laser device.

Moreover, when using a substrate whose principal plane is inclined from a particular crystal face by θ°, as in an AlGaInP semiconductor laser device shown in FIG. 11, a ridge formed by using a chemical wet etching method will have a cross section that is not in left-right symmetry as viewed from the optical path direction (waveguide direction). The expression “left-right” in the term “left-right symmetry” as used herein means “left-right” in the cross section of a semiconductor laser device as viewed from the optical path direction when the semiconductor laser device is placed with the substrate thereof facing down. For example, in the example shown in FIG. 11, the angles between the principal plane of the substrate and the opposite side surfaces of the ridge are θ1°=54.7°−θ° and θ2°=54.7°+θ°.

With a physical etching method such as ion beam etching, a ridge can be formed with a cross section that is in left-right symmetry as viewed from the optical path direction. Then, however, a physical damage may remain on the side surface of the ridge, thereby causing a leak current at the interface between the side surface of the ridge and the current blocking layer and thus lowering the current constriction effect. It may be possible as an alternative way to first form a ridge by a physical etching method and then chemically etch the side surface of the ridge before forming the current blocking layer. However, it still will result in a ridge with a cross section that is not in left-right symmetry as viewed from the optical path direction.

If the cross section of the ridge is not in left-right symmetry as viewed from the optical path direction, the cross section of the waveguide is also not in left-right symmetry as viewed from the optical path direction. Then, there is likely to be a horizontal shift (ΔP) between the peak center position of the carrier distribution pattern across the active layer and the peak center position of the intensity distribution pattern of light propagating through the waveguide. Typically, if the amount of current injected is increased to bring the semiconductor laser to a high output power state, the carrier density is relatively decreased in a region inside the active layer where the light intensity distribution is at maximum, whereby spatial hole burning of carriers is more likely to occur. Where hole burning occurs, the degree of asymmetry of the carrier distribution pattern tends to be larger as the value ΔP is larger. Therefore, in a semiconductor laser device having a larger ΔP value (i.e., a semiconductor laser device in which the cross section of the ridge as viewed from the optical path direction is more asymmetric), due to the light oscillation position in a high output power state becoming unstable, a “kink”, which is seen as a bend on a current-optical output power characteristics graph, is more likely to occur.

In a case where a semiconductor laser is used as a light source of an optical disk system, it is very important to achieve fundamental transverse mode oscillation in order to focus the output laser light onto the optical disk to a degree near the lens diffraction limit. Conventionally, if the optical output power level is about 50 mW, a semiconductor laser can maintain the fundamental transverse mode oscillation without a kink even if the cross section of the ridge is asymmetric. However, in order to realize an optical disk system capable of reading/writing data at higher rates, it is desirable to realize a semiconductor laser capable of stably achieving fundamental transverse mode oscillation even at a high output power level of 200 mW or more.

Therefore, an object of the present invention is to provide a semiconductor laser device that has a high reliability and desirable temperature characteristics while being a high-power device, a method for manufacturing the same, and an optical pickup device using the same.

A part of the object set forth above is achieved by a semiconductor laser device having the following configuration. The semiconductor laser device includes an active layer, and two cladding layers sandwiching the active layer therebetween, wherein one of the cladding layers forms a mesa-shaped ridge, and the ridge includes a waveguide region diverging into at least two branches. With this configuration, the density of carriers injected into the rear facet portion of the active layer is decreased, whereby it is possible to improve the temperature characteristics of the semiconductor laser.

Another part of the object set forth above is achieved by a method for manufacturing a semiconductor laser device having the following configuration. The method is a method for manufacturing a semiconductor laser device as set forth above, the method including a deposition step of depositing various layers including an active layer in a predetermined order by using a predetermined material for each layer; and a ridge formation step of patterning and then etching the materials deposited on the substrate, thereby forming a ridge having a waveguide region diverging into at least two branches.

According to the present invention, it is possible to provide a semiconductor laser device that has a high reliability and desirable temperature characteristics while being a high-power device, and a method for manufacturing the same. Moreover, according to the present invention, it is possible to provide an optical pickup device using such a semiconductor laser device.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a structure of a semiconductor laser device of Embodiment 1;

FIG. 2 is a schematic diagram showing the shape of a ridge as viewed from the side of the p-type GaAs contact layer in the semiconductor laser device of Embodiment 1;

FIG. 3 is a graph showing the relationship between the ridge-branching angle θ in the ridge branching region and the length Lm of the mode conversion region;

FIG. 4 is a graph showing the external differential efficiency with respect to the ridge bottom width;

FIG. 5 is a graph showing the thermal saturation level with respect to the length of the region across which the bottom width of a single ridge varies continuously in the semiconductor laser device of Embodiment 1;

FIG. 6 is a graph showing the operating current value with respect to the length of the region across which the bottom width of a single ridge varies continuously in the semiconductor laser device of Embodiment 1;

FIG. 7 is a graph showing the current-optical output power characteristics of the semiconductor laser device of Embodiment 1 being at room temperature and in a CW state;

FIG. 8A is a cross-sectional view showing a step in a method for manufacturing the semiconductor laser device of Embodiment 1;

FIG. 8B is a cross-sectional view showing the next step following the step shown in FIG. 8A;

FIG. 8C is a cross-sectional view showing the next step following the step shown in FIG. 8B;

FIG. 8D is a cross-sectional view showing the next step following the step shown in FIG. 8C;

FIG. 9 is a schematic diagram showing an optical pickup device of Embodiment 3;

FIG. 10 is a schematic diagram showing another optical pickup device of Embodiment 3; and

FIG. 11 is a front view showing a structure of a conventional semiconductor laser device.

### DESCRIPTION OF THE PREFERRED EMBODIMENTS

Preferred embodiments of the present invention will now be described with reference to the drawings. Note that in each of the following embodiments, like elements to those of any preceding embodiments may be denoted by like reference numerals, and may not be described repeatedly.

### Embodiment 1

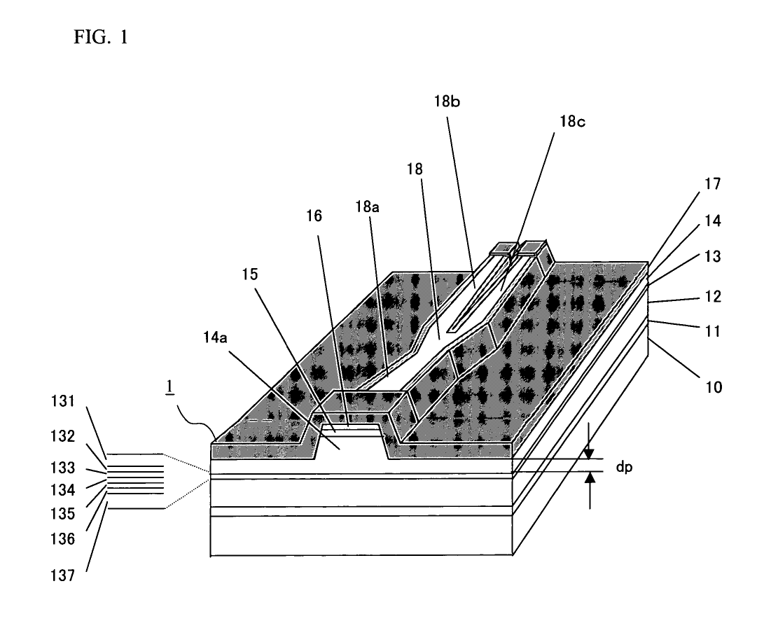

FIG. 1 shows a structure of a semiconductor laser device of Embodiment 1. A semiconductor laser device 1 of Embodiment 1 is formed on an n-type GaAs substrate 10 whose principal plane is inclined from the (100) plane by 10° in the [011] direction. An n-type GaAs buffer layer 11, an n-type (AlGa)InP first cladding layer 12, an active layer 13, a p-type (AlGa)InP second cladding layer 14, a p-type GaInP protective layer 15 and a p-type GaAs contact layer 16 are layered on the n-type GaAs substrate 10 in this order from the substrate side. The semiconductor laser device 1 has a double hetero structure including the active layer 13 and the two cladding layers sandwiching the active layer 13 therebetween.

The p-type (AlGa)InP second cladding layer 14 includes a ridge 14a having a forward mesa shape above the active layer 13. An n-type AlInP current blocking layer 17 is formed on the side surface of the ridge 14a so as to cover the ridge 14a. By a waveguide branching portion 18 provided in the resonator direction, the ridge 14a diverges into two branches from the front facet toward the rear facet. Thus, the semiconductor laser device 1 includes a waveguide region where the ridge diverges into at least two branches.

The active layer 13 is a strained quantum well active layer, and includes an (AlGa)InP first guide layer 131, a GaInP first well layer 132, an (AlGa)InP first barrier layer 133, a GaInP second well layer 134, an (AlGa)InP second barrier layer 135, a GaInP third well layer 136 and an (AlGa)InP second guide layer 137 in this order from the side of the p-type (AlGa)InP second cladding layer 14. Exemplary composition ratios will be shown later.

In the semiconductor laser device 1, the flow of a current injected through the p-type GaAs contact layer 16 is constricted within the ridge portion by the n-type AlInP current blocking layer 17, and is thus concentrated at a portion of the active layer 13 near the bottom of the ridge. Thus, it is possible to realize a population inversion that is required for laser oscillation despite a small injected current of some tens of mA. Then, with respect to the direction perpendicular to the principal plane of the active layer 13, light generated through recombination of carriers is confined by the opposing cladding layers, i.e., the n-type (AlGa)InP first cladding layer 12 and the p-type (AlGa)InP second cladding layer 14. Moreover, with respect to the direction parallel to the principal plane of the active layer 13, the generated light is confined by the n-type AlInP current blocking layer 17 having a smaller refractive index than the p-type (AlGa)InP second cladding layer 14. Thus, it is possible to realize a semiconductor laser device that is of a “ridged waveguide type”, where a ridge is used as the waveguide, and is capable of achieving fundamental transverse mode oscillation.

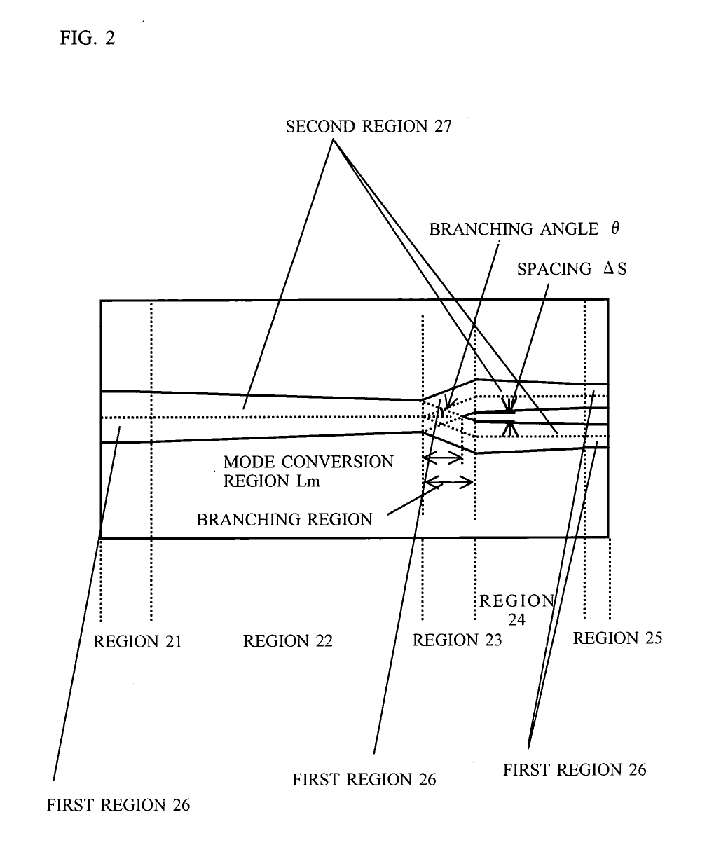

FIG. 2 is a schematic diagram showing the shape of a ridge as viewed from the side of the p-type GaAs contact layer in the semiconductor laser device of Embodiment 1. In the semiconductor laser device 1, the ridge is divided in two within the resonator so that there are two ridges extending near the rear facet in order to decrease the density of carriers injected into the rear facet portion of the active layer. Thus, it is possible to improve the temperature characteristics of the semiconductor laser.

As shown in FIG. 1, the semiconductor laser device 1 includes the waveguide branching portion 18 where a single stripe ridge diverges into two branches. Thus, the semiconductor laser device 1 includes a single stripe region 18a and two branch stripe regions 18b and 18c. In the semiconductor laser device 1 having such a configuration, there are two laser resonators, one formed by the ridge stripe 18a and the ridge stripe 18b and the other formed by the ridge stripe 18a and the ridge stripe 18c.

First, the characteristics of the semiconductor laser device 1 will be discussed qualitatively. Generally, with a semiconductor laser device formed on an inclined substrate, as is the semiconductor laser device 1 of Embodiment 1, the cross section of the ridge as viewed from the optical path direction is not in left-right symmetry, and therefore a kink is likely to occur in a high output power state. One way to improve the optical output power at which a kink occurs is to decrease the asymmetry of the carrier density distribution. For this purpose, the stripe width can be decreased so as to increase the density of carriers injected into the central portion of the stripe, thereby suppressing the spatial hole burning of carriers. Thus, by decreasing the ridge bottom width of a semiconductor laser device, it is possible to obtain a semiconductor laser device that is capable of stable oscillation up to a higher output power level.

Moreover, with a real refractive index-guided laser in which the refractive index of the current blocking layer is smaller than that of the second cladding layer where the ridge is formed and in which the current blocking layer is transparent to output laser light, it is preferred that the ridge bottom width is as small as possible in order to achieve stable fundamental transverse mode oscillation while suppressing oscillation in higher-order transverse modes.

However, if the ridge bottom width is decreased, the ridge top width is also decreased accordingly. The differential resistance Rs of a semiconductor laser device is dictated by the top width of the ridge at which the injected current is most constricted. Therefore, simply decreasing the ridge bottom width in an attempt to achieve stable oscillation up to a higher output power level may increase the differential resistance Rs, thereby increasing the operating voltage. An increase in the operating voltage also increases the operating power, thereby increasing the amount of heat generated in the semiconductor laser device, thus deteriorating the characteristic temperature T0 and lowering the reliability.

In contrast, in the semiconductor laser device 1 of the present embodiment, the ridge is divided in two within the resonator so that there are two ridges extending near the rear facet in order to decrease the density of carriers injected into the rear facet portion of the active layer. With the semiconductor laser device 1, since the ridge is divided in two near the rear facet, it is possible to increase the current injection area, thereby decreasing the differential resistance Rs in the current-voltage characteristics of the device. Therefore, with the semiconductor laser device 1, heat generation can be decreased, and the temperature characteristics can be improved.

Moreover, in the semiconductor laser device 1, the front facet, which is on the side of the single ridge stripe region (on the side of a region 21), is coated with a low-reflectivity coating, and the rear facet, which is on the side of the branched ridge stripe (on the side of a region 25), is coated with a high-reflectivity coating. Usually, when the front facet of a semiconductor laser is coated with a low-reflectivity coating while the rear facet thereof is coated with a high-reflectivity coating, it is possible to efficiently extract a high optical output power from the front facet side. In such a case, the light density in a portion of the waveguide on the front facet side is greater than that in a portion of the waveguide on the rear facet side. As a result, induced emission in the waveguide occurs with a higher intensity on the front facet side where the light density is higher, whereby the operating carrier density in a portion of the active layer on the front facet side is smaller than that on the rear facet side. In contrast, with the semiconductor laser device 1, in which the ridge is divided in two near the rear facet, the operating carrier density on the rear facet side can be decreased, and it is possible to decrease the leakage of thermally excited carriers from the active layer. Thus, it is possible to improve the temperature characteristics of the semiconductor laser device 1.

Moreover, in the semiconductor laser device 1, the ridge formed by the p-type (AlGa)InP second cladding layer 14 includes first regions 26 (regions 21, 23 and 25 to be described later) across which the ridge bottom width W is substantially constant, and second regions 27 (regions 22 and 24 to be described later) across which the ridge bottom width W varies continuously. Moreover, each of the second regions 27 of the semiconductor laser device 1 is placed between a pair of first regions 26 in the optical path direction.

In the semiconductor laser device 1 with such a configuration, by the provision of the first regions 26 across which the ridge bottom width is substantially constant, it is possible to make substantially constant the relative light-generating position with respect to the cross section of the ridge as viewed from the optical path direction. Thus, it is possible to obtain a semiconductor laser device capable of achieving stable oscillation up to a high output power level and providing a stable optical axis in the far field pattern (hereinafter “FFP”) of outputted laser light. Moreover, with the second regions 27 across which the ridge width varies continuously, it is possible to increase the width of the ridge, whereby it is possible to decrease the differential resistance Rs in the current-voltage characteristics of the device. Thus, it is possible to obtain a semiconductor laser device, in which the optical axis in FFP is stabilized and the differential resistance Rs is decreased, and which is capable of achieving fundamental transverse mode oscillation up to a high output power level. Note that the ridge bottom width being “substantially constant” as used herein means that, where the maximum value of the ridge bottom width is used as the reference, the difference between the maximum value of the ridge bottom width and the minimum value thereof is 20% or less of the maximum value.

In the semiconductor laser device 1, the ridge bottom width in each second region 27 decreases in the direction in which the resonator extends, from the front facet coated with the low-reflectivity coating toward the rear facet coated with the high-reflectivity coating. Thus, the amount of current injected into the rear facet portion of the active layer where the light density is lower can be decreased to be lower than that injected into the front facet portion of the active layer. Therefore, it is possible to inject more carriers into the front facet portion of the active layer where the light density is higher and where more injected carriers are consumed. Thus, it is possible to increase the external differential quantum efficiency ηd and to decrease the leak current. Moreover, since the operating carrier density in the rear facet portion of the active layer can be decreased, it is possible to suppress the occurrence of the spatial hole burning of carriers. Thus, it is possible to realize a semiconductor laser device in which the light distribution is stabilized and the occurrence of a kink is suppressed, and which is capable of achieving fundamental transverse mode oscillation up to a high output power level.

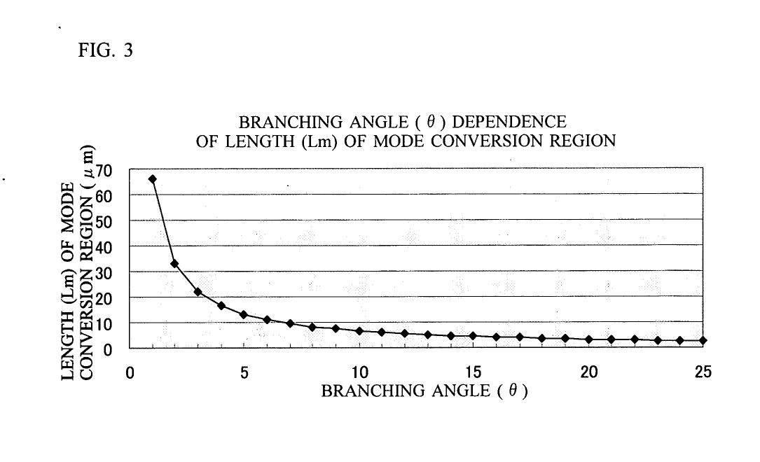

The structure of the semiconductor laser device of the present embodiment will now be described in greater detail with reference to FIGS. 3 to 7. FIG. 3 is a graph showing the relationship between the ridge-branching angle θ in the ridge branching region and the length Lm of the mode conversion region.

Referring to FIG. 3, in a range where the branching angle θ is smaller, the length Lm of the mode conversion region is larger, whereby the region with a larger stripe width extends over a larger length. As a result, the region in which higher-order transverse modes are not cut off extends over a larger length. Thus, it is indicated that there is a lower limit value for the branching angle θ in view of the transverse mode stability. In contrast, in a range where the branching angle θ is larger, the length Lm of the mode conversion region is smaller, whereby the region with a larger stripe width extends over a smaller length, and it is more difficult to achieve oscillation in higher-order transverse modes. With a greater branching angle θ, however, the angle by which the resonant mode is bent in the branching region is greater, whereby there is greater scattering loss in the waveguide. Thus, it is indicated that there is an upper limit value for the branching angle θ in order to decrease the waveguide loss.

In summary, there is an optimal value for the branching angle θ in order to realize both a transverse mode stability and a decrease in the waveguide loss. Specifically, in order to decrease the scattering loss due to the bending of the waveguide, the upper limit value for the branching angle θ is preferably 10° or less. In order to set the length Lm of the mode conversion region to be 20 μm or less and to minimize the region oscillating in higher-order transverse modes, the lower limit value for the branching angle θ needs to be 3° or more. Taking these considerations into account, the branching angle θ is 7° and the length Lm of the mode conversion region is 10 μm in the semiconductor laser device 1 of the present embodiment.

The inter-ridge spacing of the semiconductor laser device 1 will now be discussed. In the semiconductor laser device 1, the spacing ΔS between the ridges 18b and 18c depends on the length of the branching region. With a smaller spacing ΔS, heat generating regions of the active layer under the ridges 18b and 18c come closer to each other, thereby lowering the heat-radiating property, which leads to deterioration of the temperature characteristics. Thus, for a sufficient thermal separation between the heat generating regions of the active layer under the two stripe ridges 18b and 18c, the spacing ΔS is preferably 15 μm or more. Therefore, in the semiconductor laser device 1, the branching region length is set to be 100 μm, and the spacing ΔS is set to be 23 μm. With such a configuration, it is possible to decrease the operating carrier density in the rear facet portion of the active layer where the light density is lower, and to improve the temperature characteristics.

The ridge width outside the waveguide branching region 18 will now be discussed. As described above, in the semiconductor laser device 1, the ridge is divided into the first regions 26 across which the width is substantially constant and the second regions 27 across which the width varies continuously. The widths of the first regions 26 and the second regions 27 are individually controlled so as to improve the temperature characteristics and the kink level.

The length of the first region 26 (or the total length of first regions if there are more than one first regions) (the length as measured in the direction between the facets on the optical path) may be, for example, in the range of 2% to 45% of the cavity length, and is preferably in the range of 2% to 20% of the cavity length. The length of the second region 27 (or the total length of second regions if there are more than one second regions) (the length as measured in the direction between the facets on the optical path) may be, for example, in the range of 55% to 98% of the cavity length, and is preferably in the range of 98% to 80% of the cavity length. Note that the cavity length value in the semiconductor laser device is not limited to any particular value. For example, the cavity length is in the range of 800 μm to 1500 μm. For a semiconductor laser device with a power of 100 mW or more, the cavity length is set in the range of 900 μm to 1200 μm, for example, in order to realize a low leak current.

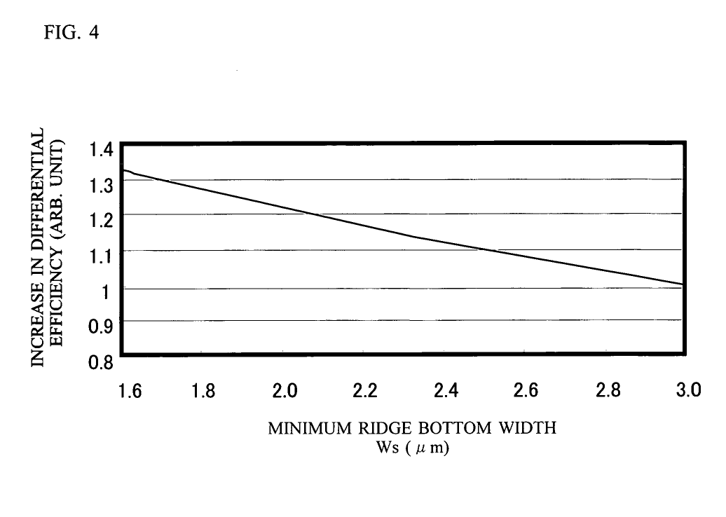

FIG. 4 is a graph showing the external differential efficiency with respect to the ridge bottom width varied as described above. In FIG. 4, the external differential quantum efficiency ηd is plotted against the minimum value of the ridge bottom width near the rear facet being varied from 1.6 μm to 3.0 μm with the ridge bottom width near the front facet being fixed to 3 μm, in terms of the ratio of the external differential quantum efficiency ηd to that of a conventional semiconductor laser device in which the ridge bottom width is fixed to 3 μm between the front and rear facets. Note that the cavity length is 1100 μm. It can be seen from FIG. 4 that the external differential quantum efficiency ηd is greater as there is a greater difference between the front-side ridge bottom width and the rear-side ridge bottom width (i.e., as the minimum value is smaller). However, the differential resistance Rs increases if the ridge bottom width is overly decreased. Thus, in the semiconductor laser device 1 of Embodiment 1, the maximum ridge bottom width on the front facet side is set to be 3.0 μm, and the minimum ridge bottom width on the rear facet side is set to be 2.0 μm.

The structure of the ridge of the semiconductor laser device 1 is not limited to the specific example described above. For example, in the semiconductor laser device 1, the ridge bottom width in the first regions 26 may be in the range from 1.8 μm to 3.5 μm. With such a semiconductor laser device, the occurrence of the spatial hole burning of carriers can be better suppressed in the first regions 26 across which the ridge bottom width is constant. Thus, it is possible to realize a semiconductor laser device in which the occurrence of a kink is suppressed up to a higher output power level.

Moreover, in the semiconductor laser device 1, the ridge bottom width in the second regions 27 may be in the range from 2.0 μm to 3.5 μm. With such a semiconductor laser device, it is possible to more effectively cut off higher-order transverse modes while better suppressing an increase in the differential resistance Rs in the second regions 27. Thus, it is possible to realize a semiconductor laser device capable of achieving fundamental transverse mode oscillation up to a higher output power level.

Moreover, in the semiconductor laser device 1, the difference between the ridge bottom width in the first regions 26 and the maximum ridge bottom width in the second regions 27 may be 0.5 μm or less. With such a semiconductor laser device, it is possible to suppress the increase in the waveguide loss due to variations in the light intensity distribution in the second regions. Thus, it is possible to realize a semiconductor laser device in which the waveguide loss is further decreased.

The length of the region across which the ridge bottom width varies continuously will now be discussed. In the semiconductor laser device 1, the ridge includes the first regions 21, 23 and 25 across which the ridge bottom width W1 is substantially constant and the second regions 22 and 24 across which the ridge bottom width W2 varies continuously. Moreover, the ridge bottom width is substantially constant at the boundaries between the regions 21 to 25, whereby the ridge side surfaces of adjacent regions are continuous with each other. The region 23 is the branching region.

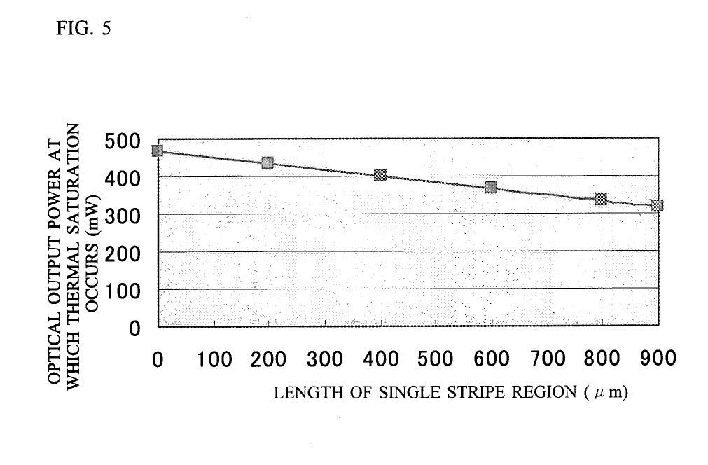

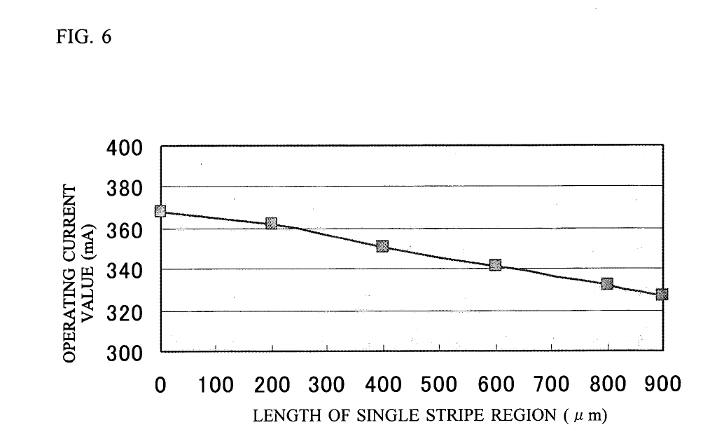

FIG. 5 is a graph showing the thermal saturation level with respect to the length of the region across which the bottom width of a single ridge varies continuously in the semiconductor laser device of Embodiment 1. FIG. 6 is a graph showing the operating current value with respect to the length of the region across which the bottom width of a single ridge varies continuously in the semiconductor laser device of Embodiment 1.

More specifically, FIG. 5 shows the thermal saturation level under pulsed mode conditions where the temperature is 75° C., the pulse width is 100 ns and the duty cycle is 50%, and FIG. 6 shows the operating current value measured at 240 mW. It can be seen from these graphs that as the length of the region 22 increases, the optical output power at which thermal saturation occurs decreases, and the operating current value also decreases. In view of this, in the semiconductor laser device 1, the length of the region 22 is set to be 600 μm so that the optical output power at which thermal saturation occurs is 350 mW or more, whereby an optical output power of 300 mW or more can be obtained stably. Note that in the semiconductor laser device 1, the lengths of the regions 21 and 24 are both 25 μm, and that of the region 23 is 100 μm. In the semiconductor laser device 1, the length of each ridge section is appropriately determined. Thus, the optical axis in FFP is stabilized, and it is possible to realize a semiconductor laser device in which the differential resistance Rs and the waveguide loss are further decreased, and which is capable of achieving fundamental transverse mode oscillation up to a high output power level.

Note that the semiconductor laser device 1 shown in FIG. 1 is merely illustrative, and the thickness, the composition, the composition ratio, the conductivity type, etc., of each layer are not limited to those shown herein. The thickness, the composition, the composition ratio, the conductivity type, etc., of each layer may be determined appropriately in view of characteristics that are needed for the semiconductor laser device. The thickness, the composition and the composition ratio of each layer may be, for example, as shown below. Note that each numerical value in parenthesis denotes the thickness of a layer, and the same reference numerals as those in FIG. 1 are used for ease of understanding.

Exemplary numerical values of the composition ratio and the thickness of each layer are as follows: the n-type GaAs buffer layer 11 (0.5 μm); the n-type (Al_{0.7}Ga_{0.3})_{0.51}In_{0.49}P first cladding layer 12 (1.2 μm); the p-type (Al_{0.7}Ga_{0.3})_{0.51}In_{0.49}P second cladding layer 14; the p-type Ga_{0.51}In_{0.49}P protective layer 15 (50 nm); and the p-type GaAs contact layer 16 (3 μm).

In the active layer 13, which is a strained quantum well active layer, exemplary numerical values of the composition ratio and the thickness of each layer are as follows: the (Al_{0.5}Ga_{0.5})_{0.51}In_{0.49}P (50 nm) first guide layer 131; the Ga_{0.48}In_{0.52}P (5 nm) first well layer 132; the (Al_{0.5}Ga_{0.5})_{0.51}In_{0.49}P (5 nm) first barrier layer 133; the Ga_{0.48}In_{0.52}P (5 nm) second well layer 134; the (Al_{0.5}Ga_{0.51})_{0.51}In_{0.49}P (5 nm) second barrier layer 135; the Ga_{0.48}In_{0.52}P (5 nm) third well layer 136; and the (Al_{0.5}Ga_{0.5})_{0.51}In_{0.49}P (50 nm) second guide layer 137.

In the p-type (Al_{0.7}Ga_{0.3})_{0.51}In_{0.49}P second cladding layer 14, an exemplary numerical value of the distance between the p-type GaInP protective layer 15 in an upper portion of the ridge and the active layer 13 is 1.2 μm, and that of the distance dp between the bottom of the ridge and the active layer is 0.2 μm. An exemplary numerical value of the thickness of the n-type AlInP current blocking layer 17 is 0.3 μm. With this exemplary numerical value, the ridge top width is smaller than the ridge bottom width by about 1 μm.

Note that the active layer 13 is not limited to the strained quantum well active layer as shown in Embodiment 1. For example, the active layer 13 may be a non-strained quantum well active layer or a bulk active layer. Moreover, the conductivity type of the active layer 13 is not limited to any particular type. For example, the conductivity type of the active layer 13 may be p type or n type, or the active layer 13 may be an undoped layer.

Moreover, as shown in FIG. 1, by using a current blocking layer that is transparent to outputted laser light, it is possible to decrease the waveguide loss and to decrease the operating current value. In such a case, since the distribution of light propagating through the waveguide can significantly seep out into the current blocking layer, the real refractive index difference (Δn) between inside and outside the stripe region can be made on the order of 10⁻³. Moreover, the value Δn can be finely controlled by adjusting the distance dp shown in FIG. 1, whereby it is possible to realize a semiconductor laser device capable of stable oscillation up to a high output power level with a decreased operating current value. Note that the range of the value Δn is, for example, 3×10⁻³ to 7×10⁻³. In this range, the semiconductor laser device is capable of achieving stable fundamental transverse mode oscillation up to a high output power level.

The value of the inclination angle θ from a particular crystal face (the (100) plane in FIG. 1) of the substrate is not limited to 10° as in the example shown in FIG. 1. For example, the inclination angle θ may be in the range of 7° to 15°. In this range, it is possible to realize a semiconductor laser device with a desirable characteristic temperature T0. If the inclination angle is below the range, the characteristic temperature T0 may decrease as the bandgap of the cladding layer is decreased by the formation of a natural superlattice. If the inclination angle is above the range, the degree of asymmetry of the cross section of the ridge as viewed from the optical path direction increases, and the crystallinity of the active layer may decrease.

A portion of the active layer near the facet may be disordered by diffusing an impurity therein. With such a semiconductor laser device, it is possible to increase the bandgap of the portion of the active layer near the facet, thereby obtaining a facet window structure that is more transparent to laser light. Thus, it is possible to realize a semiconductor laser device that is less likely to experience a facet breakdown (so called “COD”) even at higher optical output power levels.

The impurity may be, for example, Si, Zn, Mg, O, etc. The amount of impurity to be diffused (dose) may be, for example, in the range of 1×10¹⁷ cm⁻³ to 1×10²⁰ cm⁻³, and the impurity may be diffused to a distance of, for example, 10 μm to 50 μm from the facet of the semiconductor laser device.

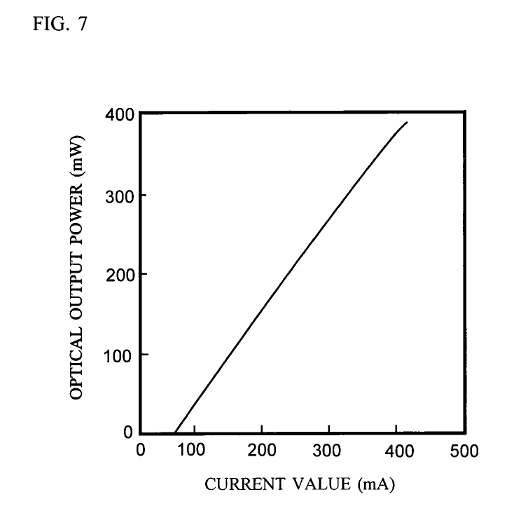

FIG. 7 is a graph showing the current-optical output power characteristics of the semiconductor laser device of Embodiment 1 being at room temperature and in a CW state. It can be seen from FIG. 7 that even at an optical output power as high as 300 mW, the semiconductor laser device maintains stable fundamental transverse mode oscillation without causing a kink.

Note that in the semiconductor laser device 1, Zn is diffused into a portion of the active layer near the facet at a dose of about 1×10¹⁹ cm⁻³, whereby the region of the active layer near the facet is in a window structure by the disordering with the impurity. Therefore, COD, which is a phenomenon in which the facet is broken by the optical output, did not occur even at an output power of 200 mW or more.

### Embodiment 2

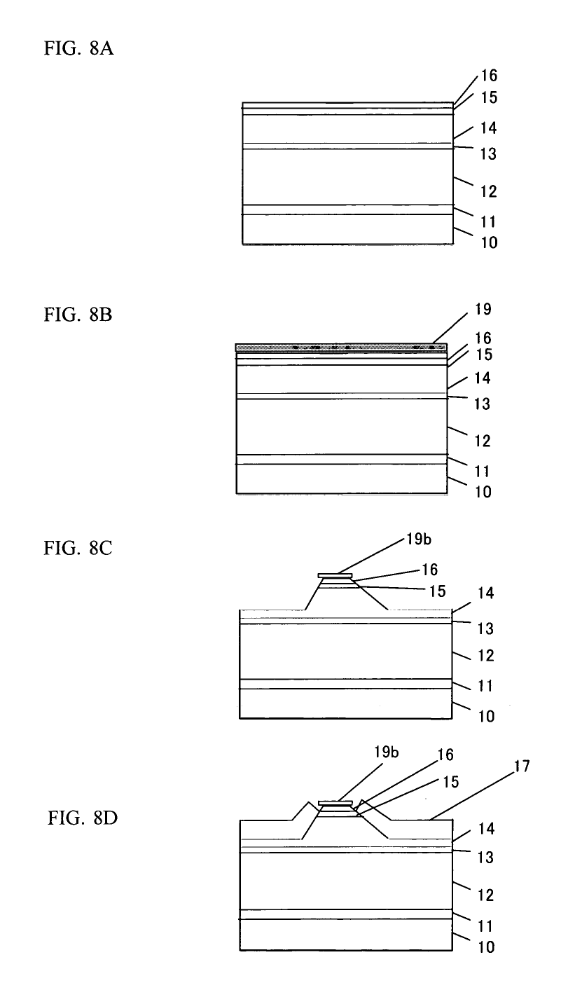

An example of a method for manufacturing a semiconductor laser device will now be described. FIGS. 8A to 8D are cross-sectional views each showing a step in the method for manufacturing a semiconductor laser device as described in Embodiment 1. First, the n-type GaAs buffer layer 11 (0.5 μm), the n-type (AlGa)InP first cladding layer 12 (1.2 μm), the active layer 13, the p-type (AlGa)InP second cladding layer 14, the p-type GaInP protective layer 15 (50 nm) and the p-type GaAs contact layer 16 (0.2 μm) are formed on then-type GaAs substrate 10 whose principal plane is inclined from the (100) plane by 100° in the [011 ] direction (deposition step: FIG. 8A). Each numerical value in parenthesis denotes the thickness of a layer. The composition ratio of each layer is not shown herein. The active layer 13 may be, for example, an active layer similar to the strained quantum well active layer of Embodiment 1. Note that composition ratios as those of Embodiment 1 may be used, for example. Each layer may be formed by, for example, an MOCVD method or an MBE method.

Then, a silicon oxide film 19 is deposited on the p-type GaAs contact layer 16, which is the uppermost layer of the layered structure (photomask formation step: FIG. 8B). The deposition may be performed by, for example, a thermal CVD method (at atmospheric pressure, 370° C). Moreover, the thickness is, for example, 0.3 μm.

Then, a portion of the silicon oxide film 19 near the facet (e.g., a portion of a 50 μm width from the facet) is removed, thereby exposing the p-type GaAs contact layer 16. Then, impurity atoms such as Zn are thermally diffused through the exposed portion, thereby disordering a region of the active layer 13 near the facet.

Then, the silicon oxide film 19 is patterned into a predetermined shape. The patterning may be performed by, for example, using a photolithography method in combination with a dry etching method. The predetermined shape may be, for example, the same shape as that of the ridge in the semiconductor laser device 1 shown in Embodiment 1. For example, the silicon oxide film 19 may be patterned into a planar shape of the ridge shown in FIG. 8C. Then, using the silicon oxide film 19b patterned in the predetermined shape as a mask, the p-type GaInP protective layer 15 and the p-type GaAs contact layer 16 are selectively etched by an etchant containing hydrochloric acid, or the like, and then the p-type AlGaInP second cladding layer 14 is selectively etched by an etchant containing sulfuric acid, an etchant containing hydrochloric acid, or the like, thereby forming a mesa-shaped ridge (ridge formation step: FIG. 8C).

Then, using the silicon oxide film 19b as a mask, the n-type AlInP current blocking layer 17 is selectively grown on the p-type AlGaInP second cladding layer 14 (blocking layer formation step: FIG. 8D). The thickness is, for example, 0.3 μm. The growth method may be, for example, an MOCVD method. Then, the silicon oxide film 19b is removed by using an etchant containing hydrofluoric acid, or the like, thus producing the semiconductor laser device 1.

The semiconductor laser device 1 can be manufactured as described above. Note that the manufacturing method is not limited to the method described above, but the semiconductor laser device 1 can be manufactured alternatively by combining other existing semiconductor manufacturing processes.

### Embodiment 3

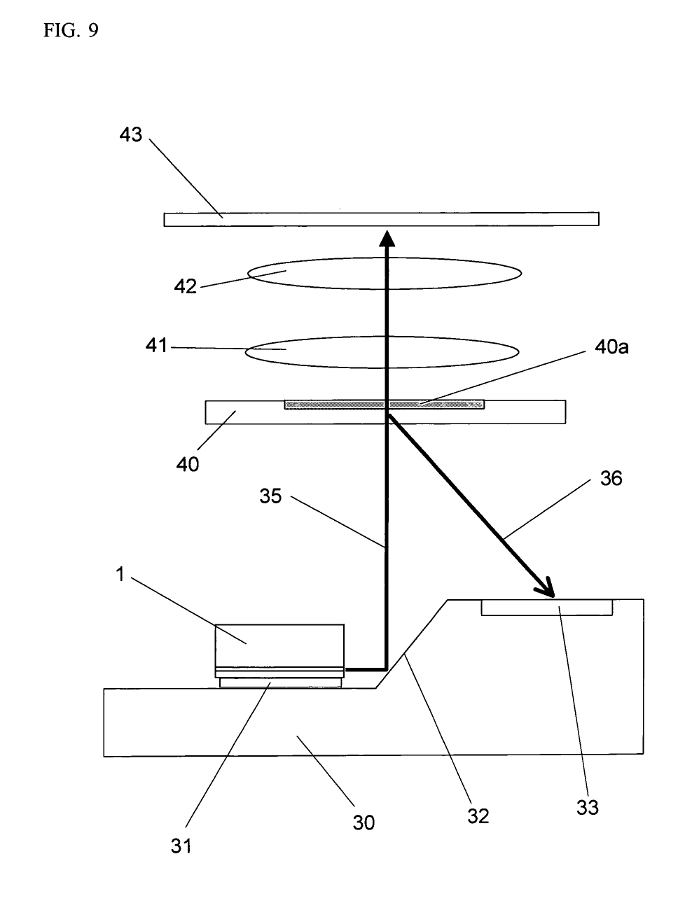

FIG. 9 is a schematic diagram showing an optical pickup device of Embodiment 3. The optical pickup device of Embodiment 3 includes the semiconductor laser device 1 being the light source, a light receiving section 33, a diffraction grating 40, a lens element 41 and a lens element 42.

The semiconductor laser device 1 has a configuration as described above in Embodiment 1, and is provided on a substrate 30 together with the light receiving section 33 including a photodiode. The semiconductor laser device 1 is placed on a base 31 so as to suppress the influence of radiated laser light 35 being reflected off the substrate 30. A reflective surface 32 is formed between the semiconductor laser device 1 and the light receiving section 33 for bending the optical path of the laser light 35 radiated from the semiconductor laser device 1. The reflective surface 32 is formed between the position where the semiconductor laser device 1 is placed and the position where the light receiving section 33 is formed, and is a plane along a crystal face obtained by a process such as wet etching. The diffraction grating 40, the lens element 41 and the lens element 42 are arranged in this order from the semiconductor laser device 1 toward an optical disk 43 along the optical path, which is bent by the reflective surface 32.

In the optical pickup device, the laser light 35 radiated from the semiconductor laser device 1 is reflected off the reflective surface 32 to travel in the normal direction to the optical disk 43, and is divided into a plurality of diffracted light beams 36 of predetermined orders through a diffractive surface 40a of the diffraction grating 40. The beams of laser light 36 separated from each other by diffraction are each focused by the lens element 41 and the lens element 42 onto a light receiving surface of the optical disk 43. Then, the beams of laser light are reflected off the light receiving surface of the optical disk 43, and are diffracted again through the diffraction grating 40, to be then incident upon the light receiving section 33. The light receiving section may be divided into a plurality of portions according to the pattern of the diffraction grating. Then, by calculating each of the input signals received by the light receiving sections, it is possible to determine the degree of focusing on the track of the optical disk surface (focus error signal) or if the laser beam is properly focused on the track (tracking error signal).

In the optical pickup device shown in FIG. 9, the light receiving section 33 and the semiconductor laser device 1 being a light outputting section are integrated together on the same substrate, thus realizing an optical pickup device of a smaller size. Moreover, with the semiconductor laser device 1, the optical axis in FFP is stabilized, and it is possible to achieve fundamental transverse mode oscillation up to a high output power level, whereby it is possible to realize an optical pickup device that is capable of accommodating optical disks of various formats such as DVD disks.

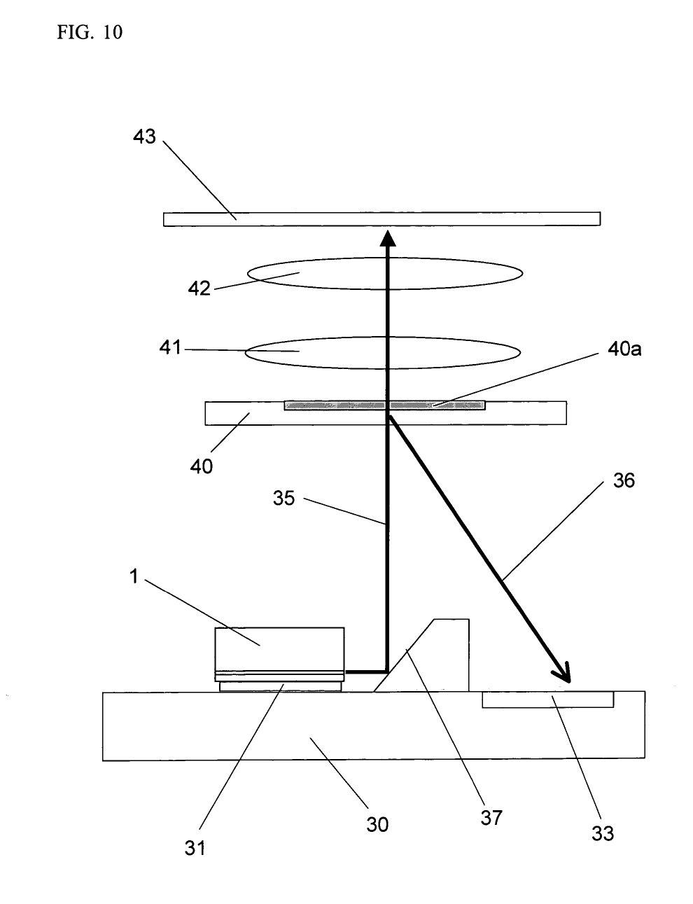

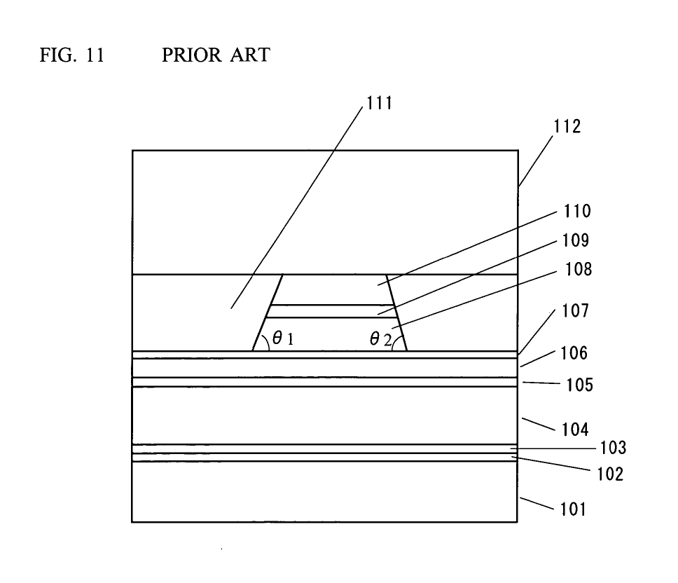

FIG. 10 is a schematic diagram showing another optical pickup device of Embodiment 3. In the optical pickup device shown in FIG. 10, the semiconductor laser device 1 and the light receiving section 33 are formed on the same substrate 30. The optical pickup device includes a reflection mirror 37 for reflecting the laser light 35 outputted from the semiconductor laser device 1 in the normal direction to the surface of the optical disk 43. Note that the semiconductor laser device 1 is placed on the base 31 so as to suppress the influence of radiated laser light 35 being reflected off the surface of the substrate 30.

An optical pickup device as described above can provide similar effects to those of the optical pickup device shown in FIG. 9.

The above description of a semiconductor laser device formed on an inclined substrate, a method for manufacturing the same, and an optical pickup device using the same has been directed to a representative case where a GaAlInP semiconductor laser device is used. Note that the present invention is not limited to any particular type of semiconductor laser device described above. The present invention can also be applicable to a semiconductor laser device formed on a just substrate with no off-orientation angle, or to any other composition or structure.

While the current blocking layer 17 is an AlInP layer in the above description, it may alternatively use a dielectric film material, such as SiO₂, SiN, amorphous silicon or Al₂O₃, having a lower bandgap and a lower refractive index than those of the cladding layer 14. Also with such a configuration, due to the insulation of the dielectric film, the current is selectively injected only into a portion under the ridge, and the light distribution can be confined in the lateral direction, whereby it is possible to achieve stable fundamental transverse mode oscillation.

A semiconductor laser device of the present invention can suitably be used in an optical pickup device for recording/reproducing data to/from magneto-optical and optical disks such as MD, CD, CD-R, CD-RW, DVD-ROM, DVD-R, DVD+R, DVD-RW, DVD+RW, HD-DVD, and Blu-Ray Disk (Registered Trademark).

While the invention has been described in detail, the foregoing description is in all aspects illustrative and not restrictive. It is understood that numerous other modifications and variations can be devised without departing from the scope of the invention.

What is claimed is:

1. A semiconductor laser device, comprising:
an active layer formed on a substrate;
two cladding layers formed on opposite surfaces of the active layer; and
a mesa-shaped ridge formed by one of the cladding layers,
wherein the ridge forms a waveguide region diverging into at least two branches.

2. The semiconductor laser device according to claim 1, wherein the semiconductor laser device includes a semiconductor layer provided on a slope of the ridge and having a lower refractive index than that of the cladding layers.

3. The semiconductor laser device according to claim 1, wherein the semiconductor laser device includes a dielectric film provided on a slope of the ridge.

4. The semiconductor laser device according to claim 3, wherein the dielectric film includes at least one layer made of one of SiO₂, SiN, amorphous silicon and Al₂O₃.

5. The semiconductor laser device according to claim 1, wherein the semiconductor laser device includes a region across which a bottom width of the ridge varies continuously.

6. The semiconductor laser device according to claim 1, wherein a bottom width of the ridge is constant near a facet of the substrate.

7. The semiconductor laser device according to claim 1, wherein the semiconductor laser device includes a front-side facet and a rear-side facet opposing each other in an optical path direction of the ridge, the front-side facet is coated with a low-reflectivity facet coating, and the rear-side facet is coated with a high-reflectivity coating.

8. The semiconductor laser device according to claim 1, wherein:
a portion of the active layer corresponding to a position of the ridge is a quantum well active layer; and
a portion of the active layer near a facet of the substrate is disordered by diffusing an impurity therein.

9. The semiconductor laser device according to claim 1, wherein the substrate is an inclined substrate.

10. An optical pickup device, comprising:
a semiconductor laser device, including an active layer formed on a substrate, two cladding layers formed on opposite surfaces of the active layer, and a mesa-shaped ridge formed by one of the cladding layers, wherein the ridge forms a waveguide region diverging into at least two branches; and
a light receiving section for receiving reflected light outputted from the semiconductor laser device and reflected off a recording medium.

11. The optical pickup device according to claim 10, further comprising a light splitting section for splitting the reflected light,
wherein the light receiving section receives the reflected light after being split by the light splitting section.

12. The optical pickup device according to claim 10, wherein the semiconductor laser device and the light receiving section are formed on the same substrate.

13. The optical pickup device according to claim 10, further comprising an optical element on the substrate for reflecting light outputted from the semiconductor laser device in a normal direction to a surface of the substrate.

14. The optical pickup device according to claim 13, wherein the optical element is a reflection mirror.

15. The optical pickup device according to claim 10, wherein the laser device further includes a semiconductor layer provided on a slope of the ridge and having a lower refractive index than that of the cladding layers.

16. The optical pickup device according to claim 10, wherein the laser device further includes a dielectric film provided on a slope of the ridge.

17. The optical pickup device according to claim 16, wherein the dielectric film includes at least one layer made of one of SiO₂, SiN, amorphous silicon and Al₂O₃.

18. The optical pickup device according to claim 10, wherein the laser device includes a region across which a bottom width of the ridge varies continuously.

19. The optical pickup device according to claim 10, wherein a bottom width of the ridge is constant near a facet of the substrate.

20. The optical pickup device according to claim 10, wherein the semiconductor laser device includes a front-side facet and a rear-side facet opposing each other in an optical path direction of the ridge, the front-side facet is coated with a low-reflectivity facet coating, and the rear-side facet is coated with a high-reflectivity coating.

21. The optical pickup device according to claim 10, wherein:
the active layer is a quantum well active layer;
a portion of the active layer near a facet of the substrate is disordered by diffusing an impurity therein.

22. The optical pickup device according to claim 10, wherein the substrate is an inclined substrate.

23. A method for manufacturing a semiconductor laser device, comprising:
a deposition step of depositing a first cladding layer, an active layer and a second cladding layer in this order on a substrate using a predetermined material for each layer; and
a ridge formation step of patterning the materials deposited on the substrate and then etching the second cladding layer, thereby forming a ridge having a waveguide region diverging into at least two branches.
